(19) United States
(12) Patent Application Publication
(10) Pub. No.: US 2024/0149810 A1
(43) Pub. Date: May 9, 2024

(54) ELECTRICAL JUNCTION BOX

(71) Applicant: Sumitomo Wiring Systems, Ltd., Yokkaichi-shi, Mie (JP)

(72) Inventor: Kazuya KOMAKI, Yokkaichi-shi, Mie (JP)

(21) Appl. No.: 18/549,022

(22) PCT Filed: Feb. 22, 2022
(86) PCT No.: PCT/JP2022/007334

§ 371 Date: Sep. 5, 2023

(30) Foreign Application Priority Data
Mar. 10, 2021 (JP) 2021-038630
Aug. 26, 2021 (JP) 2021-138136

(51) Int. Cl. B60R 16/023; H02G 3/16; H02G 5/08; H05K 7/20

(52) U.S. Cl. CPC B60R 16/0238; H02G 3/16; H02G 5/08; H05K 7/20845

(57) ABSTRACT

An electrical junction box for a vehicle includes a busbar that has a through hole at one end portion and is screwed to a relay using the through hole. The electrical junction box includes a heat absorption member that is attached to the one end portion and absorbs heat from the relay. The heat absorption member has a through hole that corresponds to the through hole and an engagement part that engages with the busbar.

### CROSS-REFERENCE TO RELATED APPLICATIONS

This application is the U.S. national stage of PCT/JP2022/007334 filed on Feb. 22, 2022, which claims priority of Japanese Patent Application No. JP 2021-038630 filed on Mar. 10, 2021 and Japanese Patent Application No. JP 2021-138136, filed on Aug. 26, 2021, the contents of which are incorporated herein.

### TECHNICAL FIELD

The present disclosure relates to an electrical junction box.

### BACKGROUND

Electrical junction boxes having a circuit with a busbar have been conventionally mounted in vehicles for conduction of relatively large electrical currents. In recent years, following the expansion of vehicle functions, the value of a current flowing into a busbar is increasing.

JP 2014-79093A discloses a power supply device that includes a relay and a busbar connected to the relay and is configured to dissipate heat generated by the relay due to the provision of a heat-dissipation fin on the busbar or bending of the busbar so as to be in contact with a chassis.

Some electronic components in an electrical junction box reach high temperatures during operation. The heat generated by the electronic components may cause components of the same to malfunction and may also have an adverse effect on surrounding electronic components, and thus heat needs to be suppressed.

In order to address this issue, in the power supply device disclosed in JP 2014-79093A, the heat generated by an electronic component (relay) is dissipated through the busbar. However, the busbar has a heat-dissipating fin or a bent part, and thus is structurally complex. In addition, the effect of the busbar suppressing an increase in heat in the electronic components is insufficient.

In view of this, an object of the present disclosure is to provide an electrical junction box that suppresses an increase in heat in an electronic component in a simple and effective manner by using a heat absorption member while enhancing the workability of assembly.

### SUMMARY

An electrical junction box according to an aspect of the present disclosure is an electrical junction box for a vehicle, the electrical junction box including a busbar that has a through hole at one end portion and is screwed to an electronic component using the through hole. The electrical junction box includes a heat absorption member that is attached to the one end portion and absorbs heat from the electronic component. The heat absorption member has a corresponding through hole that corresponds to the through hole and an engagement part that engages with the busbar.

### Advantageous Effects

According to an aspect of the present disclosure, it is possible to provide an electrical junction box that suppresses an increase in heat in an electronic component in a simple and effective manner by using a heat absorption member while enhancing the workability of assembly.

### BRIEF DESCRIPTION OF DRAWINGS

FIG. 1 is a perspective view of an electrical junction box according to a first embodiment.

FIG. 2 is a perspective view of the electrical junction box according to the first example, showing a state in which an upper case is removed.

FIG. 3 is a partial cross-sectional diagram taken along the III-III line in FIG. 2.

FIG. 4 is a cross-sectional diagram taken along the IV-IV line in FIG. 3.

FIG. 5 is a diagram showing a positional relationship between a busbar and a heat absorption member in the electrical junction box according to the first embodiment.

FIG. 6 is a perspective diagram showing the positional relationship between the busbar and the heat absorption member in the electrical junction box according to the first embodiment.

FIG. 7 is an arrow diagram taken along the VII-VII line in FIG. 5.

FIG. 8 is a diagram showing a positional relationship between a busbar and a heat absorption member in an electrical junction box according to a second embodiment.

FIG. 9 is a perspective diagram showing the positional relationship between the busbar and the heat absorption member in the electrical junction box according to the second embodiment.

FIG. 10 is an arrow diagram taken along the X-X line in FIG. 8.

FIG. 11 is a diagram showing a positional relationship between a busbar and a heat absorption member in an electrical junction box according to a third embodiment.

FIG. 12 is a perspective diagram showing the positional relationship between the busbar and the heat absorption member in the electrical junction box according to the third embodiment.

FIG. 13 is a diagram showing a positional relationship between a busbar and a heat absorption member in an electrical junction box according to a fourth embodiment.

FIG. 14 is an arrow diagram taken along the XIV arrow in FIG. 13.

FIG. 15 is a diagram showing a state in which the position of the heat absorption member in FIG. 14 is shifted.

### BRIEF DESCRIPTION OF PREFERRED EMBODIMENTS

First, embodiments of the present disclosure will be listed and described. At least some of the embodiments described below may be combined as appropriate.

An electrical junction box according to an aspect of the present disclosure is an electrical junction box for a vehicle, the electrical junction box including a busbar that has a through hole at one end portion and is screwed to an electronic component using the through hole. The electrical junction box includes a heat absorption member that is attached to the one end portion and absorbs heat from the electronic component. The heat absorption member has a corresponding through hole that corresponds to the through hole and an engagement part that engages with the busbar.

In this aspect, when the engagement part of the heat absorption member is engaged with the busbar, the corresponding through hole is aligned with the through hole of the busbar. Thus, the heat absorption member and the busbar can be screwed to the electronic component at the same time.

Therefore, it is possible to enable the heat absorption member to quickly absorb heat from the electronic component and increase the workability of assembly.

In the electrical junction box according to an aspect of the present disclosure, the busbar has an engagement through hole that engages with the engagement part.

In this aspect, the engagement part of the heat absorption member is inserted into the engagement through hole of the busbar and engages with the busbar. At this time, the corresponding through hole is aligned with the through hole of the busbar, and thus the heat absorption member and the busbar can be screwed to the electronic component at the same time.

Therefore, it is possible to enable the heat absorption member to quickly absorb heat from the electronic component and increase the workability of assembly.

In the electrical junction box according to an aspect of the present disclosure, the engagement part has a hook shape.

In this aspect, since the engagement part has a hook shape, it is possible to prevent in advance, after the engagement part of the heat absorption member has engaged with the busbar, the engaged state from being released.

This further enhances the workability of assembly.

In the electrical junction box according to an aspect of the present disclosure, the busbar is provided with a cutout that engages with the engagement part, at a side edge of the busbar.

In this aspect, the cutout is formed at the side edge of the busbar, and the engagement part of the heat absorption member engages with the cutout.

This allows a worker to easily engage the engagement part and the cutout, which further increases the workability of assembly.

In the electrical junction box according to an aspect of the present disclosure, the heat absorption member is made of copper or aluminum.

In this aspect, the heat absorption member is made of a highly heat-conductive material such as copper or aluminum, and thus it is possible to quickly absorb heat from the electronic component.

The present disclosure will be specifically described with reference to the drawings showing embodiments of the present disclosure. An electrical junction box according to the embodiments of the present disclosure will be described below with reference to the drawings. It should be noted that the present disclosure is not limited to the examples herein, but rather is indicated by the claims, and is intended to include all modifications within a meaning and scope equivalent to the claims.

Hereinafter, the embodiments will be described taking an electrical junction box housing, for example a relay serving as an electronic component.

### FIRST EMBODIMENT

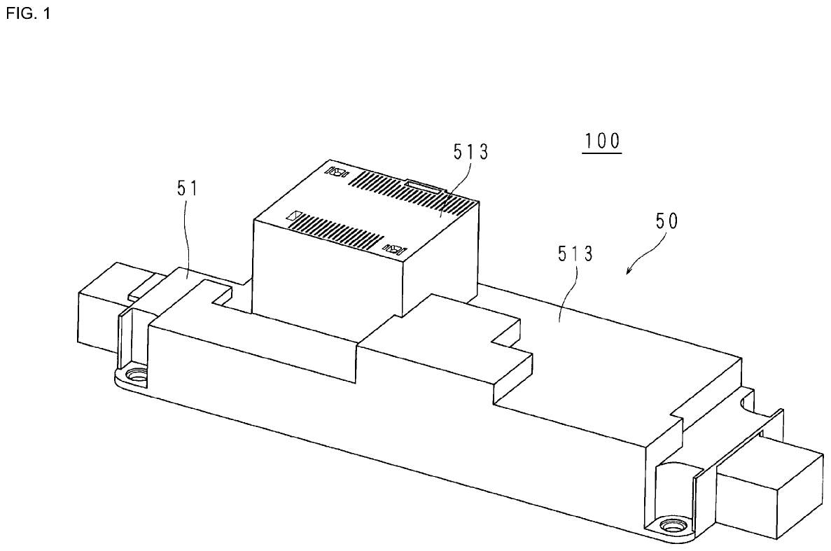

FIG. 1 is a perspective view of an electrical junction box 100 according to a first embodiment. The electrical junction box 100 includes a housing casing 50 that houses electronic components. The housing casing 50 is made of a metal or a resin, for example, and houses a relay 10 described later.

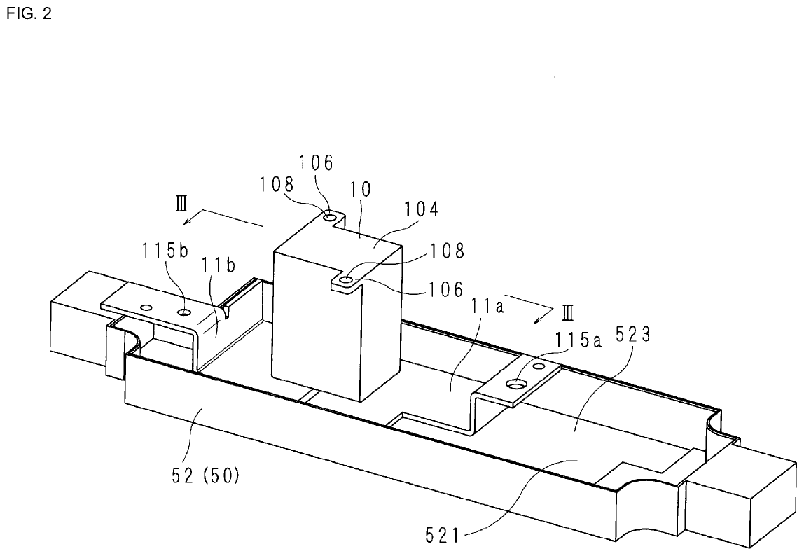

FIG. 2 is a perspective view of the electrical junction box 100 according to the first example, showing a state in which an upper case 51 is removed.

In the electrical junction box 100, the housing casing 50 includes the upper case 51 to which the relay 10 is fixed and a lower case 52 that is covered by the upper case 51. The electrical junction box 100 is attached to a battery pack of an electric vehicle (EV), for example. The electrical junction box 100 is attached such that a bottom plate 521 of the lower case 52 is in contact with the battery pack of the EV.

The relay 10 is fixed to a ceiling plate 513 of the upper case 51 as described later. Busbars 11a and 11b are provided in the vicinity of an inside surface 523 of the bottom plate 521 of the lower case 52 that faces the ceiling plate 513. The busbars 11a and 11b are partially interposed between the relay 10 and the inside surface 523. Hereinafter, the busbars 11a and 11b will also be referred to as busbars 11 for the sake of convenience.

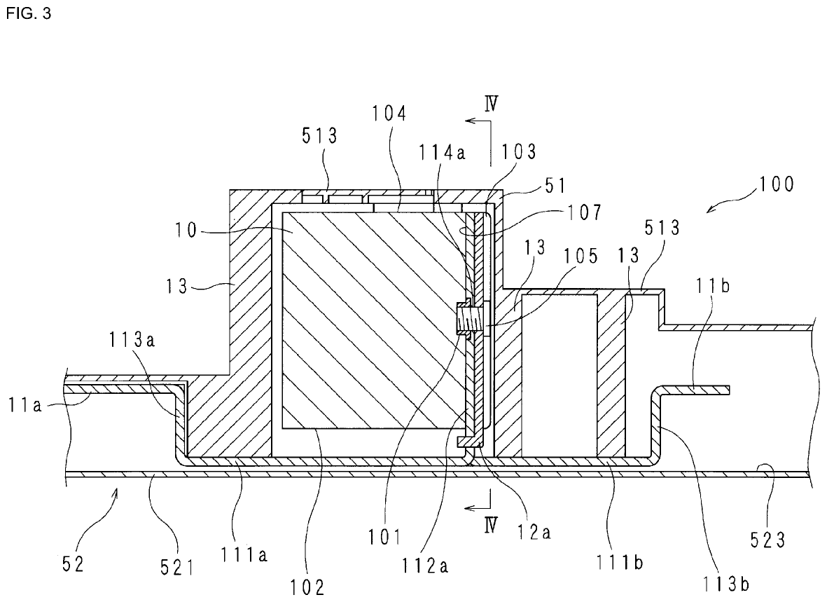

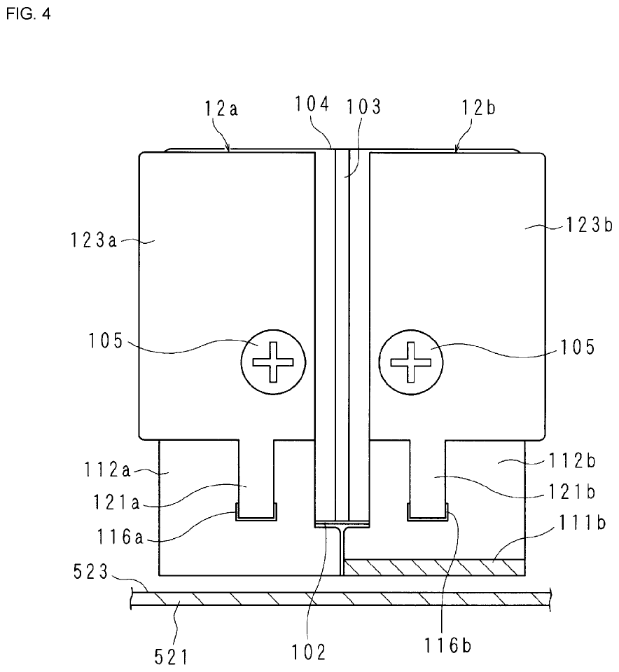

FIG. 3 is a partial cross-sectional view taken along the III-III line in FIG. 2. FIG. 4 is a cross-sectional view taken along the IV-IV line in FIG. 3.

The relay 10 is switched ON when the vehicle is caused to travel, and is switched OFF when the vehicle is not being caused to travel, for example. The relay 10 has a rectangular parallelepiped box shape and is provided such that one surface 102 of the relay 10 faces the busbars 11 (the inside surface 523).

The relay 10 also has two connecting pieces 106 on another surface 104 on the side opposite to the one surface 102 (see FIG. 2). The connecting pieces 106 are respectively connected to two opposing edges of the other surface 104. The two connecting pieces 106 are provided in the direction of a diagonal line and extend from the corresponding edges of the other surface 104 along the other surface 104. Each connecting piece 106 has a through hole 108 that extends through the connecting piece 106 in a thickness direction. Bolts (not shown) are passed through the through holes 108 and screwed to screw holes in the ceiling plate 513 of the upper case 51, for example, thus fixing the relay 10 to the upper case 51.

The relay 10 also has four side surfaces that stand perpendicular to the four side edges of the one surface 102 in a rectangular shape. One side surface 107 of the four side surfaces has a terminal 101 as described later. That is, the relay is provided such that the one surface 102 faces the inside surface 523 and the side surface 107 intersects the inside surface 523.

The side surface 107 has a rectangular shape in which the opposing direction of the ceiling plate 513 and the bottom plate 521 (hereinafter, referred to as the vertical direction) is the longitudinal direction of the rectangular shape. The side surface 107 has two terminals 101. The two terminals 101 are arranged side by side in a direction intersecting the vertical direction (hereinafter, referred to as the horizontal direction). The two terminals 101 are respectively connected to the busbars 11a and 11b. FIG. 3 shows only one terminal 101.

Each terminal 101 has a cylindrical shape. The terminals 101 are largely embedded in the relay 10 and only one end portion of each terminal 101 is exposed from the side surface 107. Each terminal 101 has a screw thread on the inner peripheral surface thereof.

The side surface 107 of the relay 10 has a partition plate 103 that stands perpendicular to the side surface 107 between the two terminals 101. The two terminals 101 are partitioned by the partition plate 103. The partition plate 103 has a substantially thin rectangular shape and extends in the vertical direction.

The busbars 11 are formed using metal plates with favorable conductivity, for example. The busbar 11a is connected to one of the two terminals 101 of the relay 10, and the busbar 11b is connected to the other terminal 101.

The busbar 11a has a flat part 111a that faces the one surface 102 of the relay 10 and the inside surface 523 of the bottom plate 521. The busbar 11a also has a contact part 112a and a fixation part 113a that extend in the vertical direction and are respectively connected to two opposing side edges of the flat part 111a.

The contact part 112a has a substantially rectangular shape whose vertical direction is the longitudinal direction, and is disposed adjacent to the side surface 107 of the relay 10. The contact part 112a extends along the side surface 107 and has a through hole 114a at a substantially central portion in the vertical direction thereof. The contact part 112a also has a rectangular through hole 116a (engagement through hole) that extends therethrough in the thickness direction at an end portion near the flat part 111a.

The fixation part 113a has an end portion that is bent parallel to the bottom plate 521. This end portion has a through hole 115a (see FIG. 2). The fixation part 113a (the busbar 11a) is fixed to the lower case 52 using the through hole 115a.

The busbar 11b has a flat part 111b facing the inside surface 523 of the bottom plate 521. The busbar 11b also has a contact part 112b and a fixation part 113b that extend in the vertical direction and are respectively connected to two opposing side edges of the flat part 111b.

The contact part 112b has a substantially rectangular shape whose vertical direction is the longitudinal direction, and is disposed adjacent to the side surface 107 of the relay 10. The contact part 112b extends along the side surface 107 and has a through hole (not shown) at a substantially central portion in the vertical direction thereof. The contact part 112b also has a rectangular through hole 116b (engagement through hole) that extends therethrough in the thickness direction at an end portion near the flat part 111b.

The fixation part 113b has an end portion that is bent parallel to the bottom plate 521. The end portion has a through hole 115b (see FIG. 2). The fixation part 113b (the busbar 11b) is fixed to the lower case 52 using the through hole 115b.

The ceiling plate 513 of the upper case 51 has a pressing part 13 that protrudes to press the busbars 11 against the bottom plate 521. The pressing part 13 vertically extends from the ceiling plate 513 and presses the flat part 111a of the busbar 11a and the flat part 111b of the busbar 11b against the bottom plate 521.

For example, the pressing part 13 is formed as one piece with the upper case 51. Upon completion of assembly of the electrical junction box 100, the leading end of the pressing part 13 is in constant contact with the flat parts 111a and 111b to press the busbar 11a and the busbar 11b against the bottom plate 521. Incidentally, the relay 10 reaches high temperatures during operation.

The heat may cause components of the same to malfunction and may also have an adverse effect on electronic components surrounding the relay 10, and thus needs to be suppressed.

In the electrical junction box 100 according to the first embodiment, the heat generated by the relay 10 is absorbed and dispersed by using thermal mass (a property of drawing and storing heat) or another member that increases thermal capacity. This makes it possible to suppress an increase in heat in the relay 10 in an easy and effective manner. As such another member, in the electrical junction box 100, heat absorption members 12a and 12b are attached to the connection part between the relay 10 and the busbars 11, as shown in FIG. 4. That is, the heat absorption member 12a is attached to the busbar 11a, and the heat absorption member 12b is attached to the busbar 11b. Hereinafter, this will be described in detail with reference to the drawings.

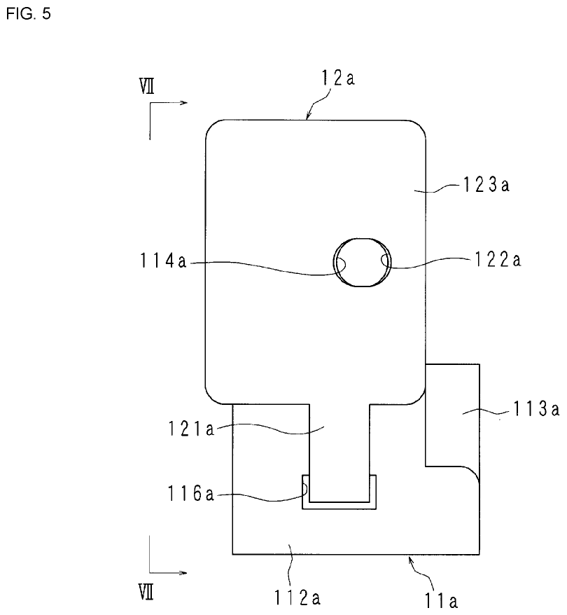

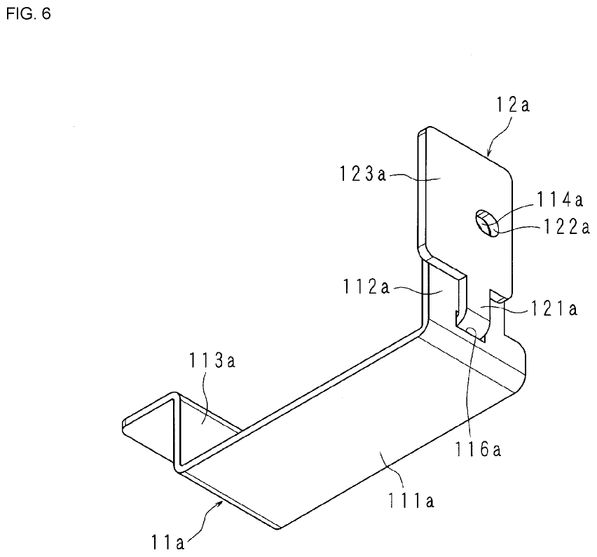

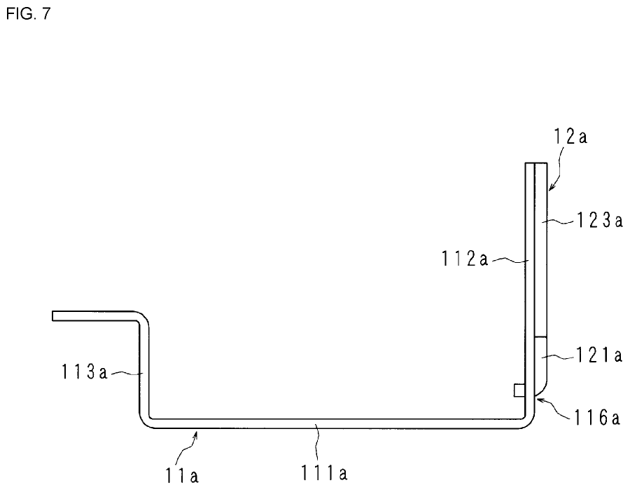

FIG. 5 is a diagram showing a positional relationship between the busbar 11a and the heat absorption member 12a in the electrical junction box 100 according to the first embodiment. FIG. 6 is a perspective diagram showing the positional relationship between the busbar 11a and the heat absorption member 12a in the electrical junction box 100 according to the first embodiment. FIG. 7 is an arrow diagram taken along the VII-VII line in FIG. 5. FIGS. 5 to 7 show only the busbar 11a and the heat absorption member 12a for the sake of convenience.

As described above, the contact part 112a of the busbar 11a is disposed adjacent to the side surface 107 of the relay 10 so that one surface thereof faces the side surface 107. The heat absorption member 12a is attached to another surface of the contact part 112a.

The heat absorption member 12a is formed using a plate member made of a metal such as Al, Cu, or the like, for example, and the material may be the same as the material of the busbar 11a. The heat absorption member 12a has a rectangular plate 123a that extends vertically. The vertical length of the rectangular plate 123a is shorter than the vertical length of the contact part 112a, and the horizontal length of the rectangular plate 123a is longer than the horizontal length of the contact part 112a. The rectangular plate 123a has a through hole 122a (corresponding through hole) that extends therethrough in the thickness direction at a substantially central portion in the vertical direction.

The heat absorption member 12a has an engagement part 121a that engages with the contact part 112a and is connected to a substantially central portion of, out of the two short sides of the rectangular plate 123a, one short side near the flat part 111a. The engagement part 121a has an L-shape in a vertical cross sectional view. That is, the engagement part 121a has a thin strip shape and has a leading end portion that is bent toward the contact part 112a. The leading end portion of the engagement part 121a engages with the rectangular through hole 116a of the contact part 112a.

That is, the leading end portion of the engagement part 121a is rectangular in a cross-sectional view, and the rectangular through hole 116a of the contact part 112a has a shape that corresponds to the leading end portion of the engagement part 121a. As shown in FIGS. 5 to 7, the leading end portion of the engagement part 121a is inserted into the rectangular through hole 116a and the engagement part 121a (the heat absorption member 12a) is engaged with the contact part 112a.

Accordingly, the heat absorption member 12a is positioned relative to the contact part 112a. That is, when the engagement part 121a is engaged with the contact part 112a (the rectangular through hole 116a), the other short side of the rectangular plate 123a is aligned with the short side of the contact part 112a, and the position of the through hole 122a of the rectangular plate 123a is aligned with the position of the through hole 114a of the contact part 112a (see FIG. 5).

In this manner, when the through hole 122a of the rectangular plate 123a and the through hole 114a of the contact part 112a are aligned with each other, the heat absorption member 12a and the contact part 112a (the busbar 11a) are screwed to the relay 10 using a bolt 105 (see FIGS. 3 and 4).

That is, the heat absorption member 12a and the contact part 112a (the busbar 11a) are fixed to the terminal 101 by inserting the bolt 105 into the through hole 122a and the through hole 114a and screwing the bolt 105 into the terminal 101. The busbar 11a is electrically connected to the terminal 101 of the relay 10, and the heat absorption member 12a is pressure-welded to the busbar 11a.

The contact part 112b of the busbar 11b has one surface facing the side surface 107 and another surface to which the heat absorption member 12b is attached. The heat absorption member 12b has a rectangular plate 123b and an engagement part 121b. As shown in FIG. 4, the leading end portion of the engagement part 121b is inserted into the rectangular through hole 116b of the contact part 112b, and the engagement part 121b (the heat absorption member 12b) is engaged with the contact part 112b. At this time, the through hole (not shown) of the rectangular plate 123b and the through hole (not shown) of the contact part 112b are aligned with each other. The heat absorption member 12b and the contact part 112b (the busbar 11b) are screwed to the relay 10 by inserting the bolt 105 into the through hole of the rectangular plate 123b and the through hole of the contact part 112b and screwing the bolt 105 into the terminal 101 (see FIG. 4).

The heat absorption members 12a and 12b have substantially the same shape, and the positional relationship between the busbar 11a and the heat absorption member 12a is similar to the positional relationship between the busbar 11b and the heat absorption member 12b, and thus a detailed description of the heat absorption member 12b will be omitted.

As stated above, in the electrical junction box 100 according to the first embodiment, the heat absorption member 12a is attached to the busbar 11a, and the heat absorption member 12b is attached to the busbar 11b, at the connection part between the relay 10 and the busbars 11.

Therefore, at the time of power distribution, the heat generated by the relay 10 is quickly transferred to and absorbed by the heat absorption members 12a and 12b via the contact parts 112a and 112b. The heat absorption member 12a and 12b can store a significantly large amount of heat from the relay 10, and can disperse the heat from the relay 10 to suppress an excessive temperature increase in the relay 10 and the contact parts 112a and 112b. The heat absorbed by the heat absorption members 12a and 12b is air-cooled via the surfaces of the heat absorption members 12a and 12b.

When assembling the electrical junction box 100 according to the first embodiment, a worker inserts the engagement parts 121a and 121b of the heat absorption members 12a and 12b into the rectangular through holes 116a and 116b of the contact parts 112a and 112b, respectively, aligns the through hole 122a of the rectangular plate 123a and the through hole 114a of the contact part 112a, and aligns the through hole of the rectangular plate 123b and the through hole of the contact part 112b. In this aligned state, the worker inserts a bolt 105 into the through hole 122a of the rectangular plate 123a and the through hole 114a of the contact part 112a and screws the bolt 105 into the corresponding terminal 101, and inserts a bolt 105 into the through hole of the rectangular plate 123b and the through hole of the contact part 112b and screws the bolt 105 into the corresponding terminal 101.

At this time, since the engagement parts 121a and 121b and the rectangular through holes 116a and 116b are engaged with each other, when the worker rotates the bolts 105, the heat absorption members 12a and 12b can be prevented in advance from rotating along with the bolts 105 and shifting in position due to the rotation, thus increasing the workability.

Further, the engagement between the engagement parts 121a and 121b of the heat absorption members 12a and 12b and the rectangular through holes 116a and 116b of the contact parts 112a and 112b aligns the through hole 122a of the rectangular plate 123a and the through hole 114a of the contact part 112a, and aligns the through hole of the rectangular plate 123b and the through hole of the contact part 112b. This reduces tolerances and makes for easier designing.

As described above, the heat in the relay 10 absorbed by the heat absorption members 12a and 12b is air-cooled via the surfaces of the heat absorption members 12a and 12b. Therefore, the heat absorption members 12a and 12b may have protrusions and recessions on the surfaces that are not in contact with the contact parts 112a and 112b. In this case, the areas of the heat absorption members 12a and 12b in contact with air are increased, and thus heat accumulated in the heat absorption members 12a and 12b is air-cooled in a more effective manner.

In the foregoing description, the relay 10 is taken as an example of an electronic component that generates heat during operation. However, the present disclosure is not limited to this. It goes without saying that the present disclosure is also applicable to other electronic components such as a semiconductor switch, for example.

### SECOND EMBODIMENT

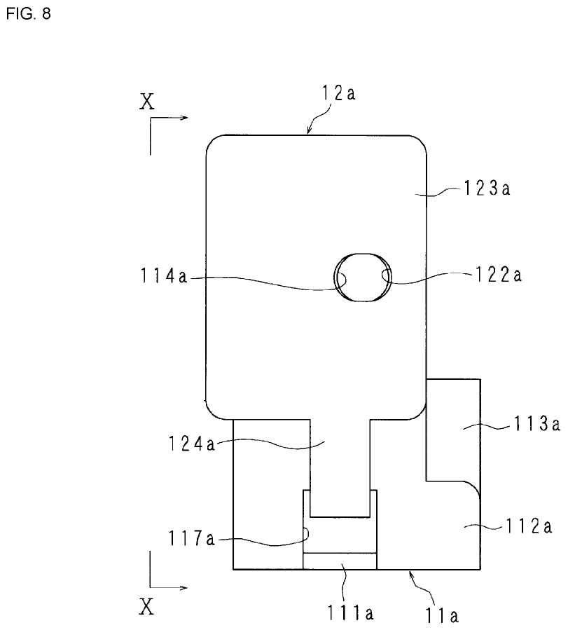

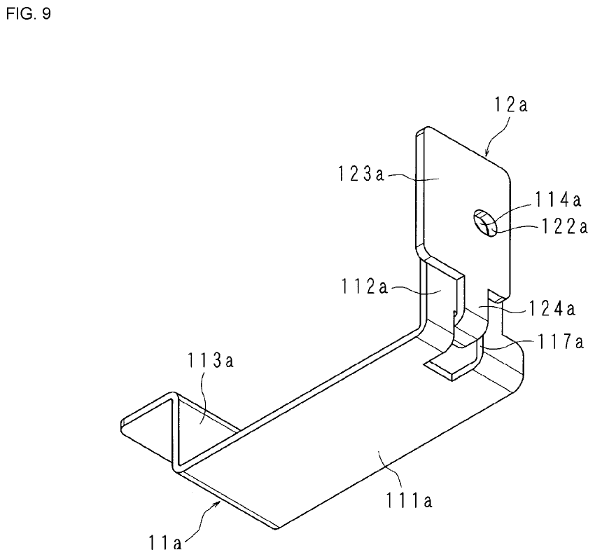

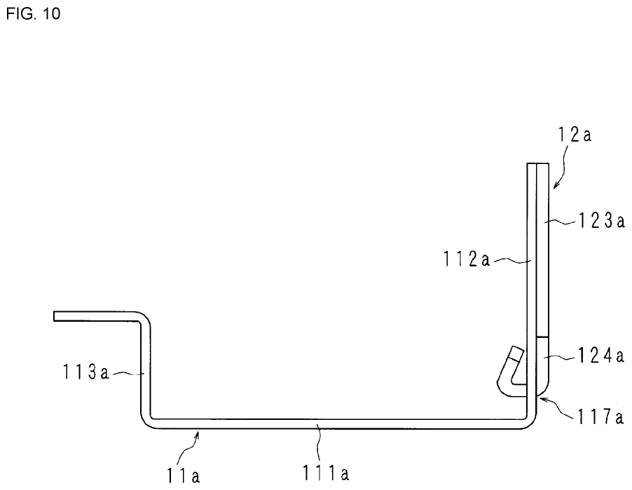

FIG. 8 is a diagram showing a positional relationship between the busbar 11a and the heat absorption member 12a in the electrical junction box 100 according to a second embodiment. FIG. 9 is a perspective diagram showing the positional relationship between the busbar 11a and the heat absorption member 12a in the electrical junction box 100 according to the second example. FIG. 10 is an arrow diagram taken along the X-X line in FIG. 8. FIGS. 8 to 10 show only the busbar 11a and the heat absorption member 12a for the sake of convenience.

The electrical junction box 100 according to the second embodiment includes busbars 11a and 11b and heat absorption members 12a and 12b similarly to the first embodiment. The heat absorption members 12a and 12b have substantially the same shape, and the positional relationship between the busbar 11a and the heat absorption member 12a is similar to the positional relationship between the busbar 11b and the heat absorption member 12b. Thus, the following description will be provided taking the busbar 11a and the heat absorption member 12a as an example with reference to FIGS. 8 to 10, and a description of the busbar 11b and the heat absorption member 12b will be omitted.

In the electrical junction box 100 according to the second embodiment, the busbar 11a has an engagement hole 117a (engagement through hole) that engages with the heat absorption member 12a. The engagement hole 117a is formed spanning from the flat part 111a to the contact part 112a. That is, the engagement hole 117a is formed by cutting out central portions of the flat part 111a and the contact part 112a in the width direction in a substantially rectangular shape, from the end portion of the flat part 111a close to the contact part 112a to the end portion of the contact part 112a close to the flat part 111a. As in the first embodiment, the heat absorption member 12a is attached to the other surface of the contact part 112a of the busbar 11a.

The heat absorption member 12a has the rectangular plate 123a that extends in the vertical direction. The vertical length of the rectangular plate 123a is shorter than the vertical length of the contact part 112a, and the horizontal length of the rectangular plate 123a is longer than horizontal length of the contact part 112a. The rectangular plate 123a has the through hole 122a that extends therethrough in the thickness direction at a substantially central portion in the vertical direction.

In the heat absorption member 12a, an engagement part 124a that engages with the contact part 112a is connected to a substantially central portion of, out of the two short sides of the rectangular plate 123a, one short side on the flat part 111a side. The engagement part 124a has a thin strip shape and its leading end portion is bent toward the contact part 112a in the shape of a hook (see FIG. 10). The end portion of the engagement part 124a engages with the engagement hole 117a of the busbar 11a.

That is, the length of the end portion of the engagement part 124a in the width direction of the engagement part 124a is smaller than the length of the engagement hole 117a in the width direction of the contact part 112a. As shown in FIGS. 8 to 10, the end portion of the engagement part 124a is inserted into the engagement hole 117a, and the engagement part 124a (the heat absorption member 12a) is engaged with the contact part 112a. Since the end portion of the engagement part 124a has a hook shape as described above, the leading end of the engagement part 124a is caught on the one surface side of the contact part 112a.

As stated above, when the engagement part 124a is engaged with the contact part 112a (the engagement hole 117a), the position of the through hole 122a of the rectangular plate 123a aligns with the position of the through hole 114a of the contact part 112a, as shown in FIG. 8. In addition, the heat absorption member 12a is restricted from moving in a direction away from the contact part 112a.

In this manner, when the through hole 122a of the rectangular plate 123a and the through hole 114a of the contact part 112a are aligned with each other, the bolt 105 is inserted into the through hole 122a and the through hole 114a and screwed to the terminal 101 so that the heat absorption member 12a and the contact part 112a (the busbar 11a) are fixed to the terminal 101 (see FIG. 4). The busbar 11a is electrically connected to the terminal 101 of the relay 10, and the heat absorption member 12a is pressure-welded to the busbar 11a.

Therefore, in the electrical junction box 100 according to the second embodiment, the heat generated by the relay 10 during power distribution is quickly absorbed by the heat absorption member 12a via the contact part 112a. The heat absorption member 12a can disperse heat from the relay 10 and suppress an excessive temperature increase in the relay 10 and the contact part 112a.

When assembling the electrical junction box 100 according to the second embodiment, a worker engages the engagement part 124a with the contact part 112a (the engagement hole 117a), and aligns the through hole 122a of the rectangular plate 123a with the through hole 114a of the contact part 112a. In this state, the worker inserts the bolt 105 into the through hole 122a of the rectangular plate 123a and the through hole 114a of the contact part 112a and screws the bolt 105 into the corresponding terminal 101.

At this time, since the engagement part 124a and the engagement hole 117a are engaged with each other, when the worker rotates the bolt 105, the heat absorption member 12a can be prevented in advance from rotating along with the bolt 105 and shifting in position due to the rotation, thus increasing the workability.

Further, in the electrical junction box 100 according to the second embodiment, since the end portion of the engagement part 124a has a hook shape as described above, when the engagement part 124a is engaged with the engagement hole 117a, the end portion of the engagement part 124a is caught on the contact part 112a, and the heat absorption member 12a is restricted from moving in a direction away from the contact part 112a. This further increases the workability.

In the electrical junction box 100 according to the second embodiment, the engagement hole 117a that engages with the heat absorption member 12a (the engagement part 124a) is formed over a wide area spanning from the flat part 111a to the contact part 112a. Accordingly, when engaging the engagement part 124a and the engagement hole 117a, the worker can easily insert the engagement part 124a into the engagement hole 117a. This further increases the workability.

In the foregoing description, the busbar 11a and the heat absorption member 12a were taken as an example. However, it goes without saying that the busbar 11b and the heat absorption member 12b are similarly configured to obtain similar advantageous effects.

Components similar to those in the first embodiment are given identical reference signs and detailed descriptions thereof are omitted.

### THIRD EMBODIMENT

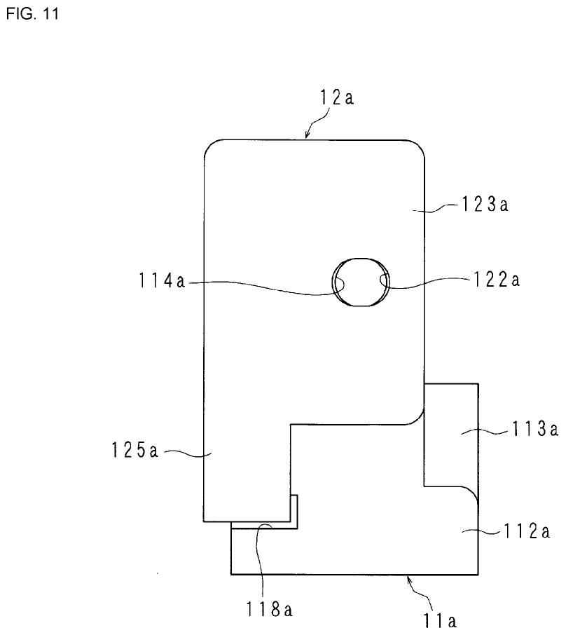

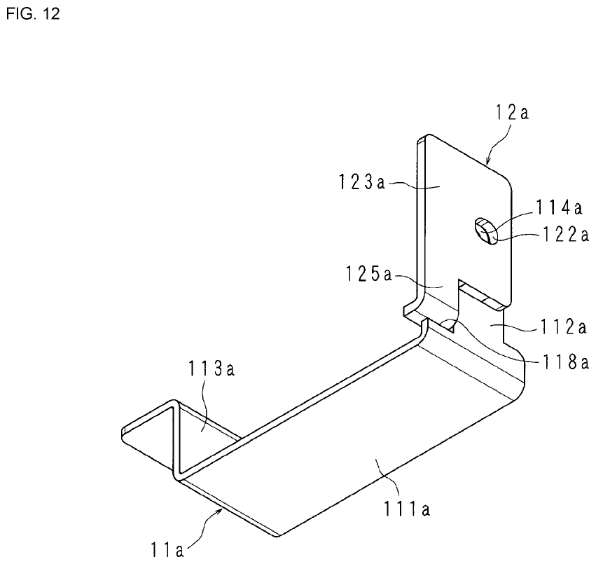

FIG. 11 is a diagram showing a positional relationship between the busbar 11a and the heat absorption member 12a in the electrical junction box 100 according to a third embodiment. FIG. 12 is a perspective diagram showing the positional relationship between the busbar 11a and the heat absorption member 12a. FIGS. 11 and 12 show only the busbar 11a and the heat absorption member 12a for the sake of convenience.

The electrical junction box 100 according to the third embodiment includes busbars 11a and 11b and heat absorption members 12a and 12b similarly to the first embodiment. The heat absorption members 12a and 12b have substantially the same shape, and the positional relationship between the busbar 11a and the heat absorption member 12a is similar to the positional relationship between the busbar 11b and the heat absorption member 12b. Thus, the following description will be provided taking the busbar 11a and the heat absorption member 12a as an example with reference to FIGS. 11 and 12, and a description of the busbar 11b and the heat absorption member 12b will be omitted.

In the electrical junction box 100 according to the third embodiment, the busbar 11a has a cutout 118a that engages with the heat absorption member 12a. The cutout 118a is formed at an end portion of the busbar 11a closer to a flat part 111a at the edge portion of one long side of the contact part 112a. The cutout 118a is rectangular and extends perpendicular from the edge portion of the contact part 112a.

As in the first embodiment, the heat absorption member 12a is attached to the other surface of the contact part 112a of the busbar 11a.

The heat absorption member 12a has a rectangular plate 123a that extends in the vertical direction. The vertical length of the rectangular plate 123a is shorter than the vertical length of the contact part 112a, and the horizontal length of the rectangular plate 123a is longer than the horizontal length of the contact part 112a. The rectangular plate 123a has the through hole 122a that extends therethrough in the thickness direction at a substantially central portion in the vertical direction.

In the heat absorption member 12a, an engagement part 125a that engages with the contact part 112a is connected to one end portion of, out of the two short sides of the rectangular plate 123a, one short side on the flat part 111a side. The engagement part 125a has an L-shape in a vertical cross-section view. That is, the engagement part 125a has a rectangular shape and its leading end portion is bent toward the contact part 112a and engages with the cutout 118a of the contact part 112a.

That is, the leading end portion of the engagement part 125a is rectangular in a cross-sectional view, and the cutout 118a of the contact part 112a has a shape that corresponds to the leading end portion of the engagement part 125a. As shown in FIGS. 11 and 12, the leading end portion of the engagement part 125a is inserted into the cutout 118a and the engagement part 125a (the heat absorption member 12a) engages with the contact part 112a.

As described above, when the engagement part 125a is engaged with the contact part 112a (the cutout 118a), the position of the through hole 122a of the rectangular plate 123a aligns with the position of the through hole 114a of the contact part 112a as shown in FIG. 11.

In this manner, when the through hole 122a of the rectangular plate 123a and the through hole 114a of the contact part 112a are aligned with each other, the bolt 105 is inserted into the through hole 122a and the through hole 114a and screwed to the corresponding terminal 101 so that the heat absorption member 12a and the contact part 112a (the busbar 11a) are fixed to the terminal 101 (see FIG. 4). The busbar 11a is electrically connected to the terminal 101 of the relay 10, and the heat absorption member 12a is pressure-welded to the busbar 11a.

Therefore, in the electrical junction box 100 according to the third embodiment, heat generated by the relay 10 during power distribution is quickly absorbed by the heat absorption member 12a via the contact part 112a. This makes it possible to suppress an excessive temperature increase in the relay 10 and the contact part 112a.

When assembling the electrical junction box 100 according to the third embodiment, a worker engages the engagement part 125a with the contact part 112a (the cutout 118a) and aligns the through hole 122a of the rectangular plate 123a with the through hole 114a of the contact part 112a. In this state, the worker inserts the bolt 105 into the through hole 122a of the rectangular plate 123a and the through hole 114a of the contact part 112a and screws the bolt 105 into the corresponding terminal 101.

At this time, since the engagement part 125a and the cutout 118a are engaged with each other, when the worker rotates the bolt 105, the heat absorption member 12a can be prevented in advance from rotating along with the bolt 105 and shifting in position due to the rotation, thus increasing the workability.

In the electrical junction box 100 according to the third embodiment, the cutout 118a engaging with the heat absorption member 12a (the engagement part 125a) is formed at the end portion of a long-side edge portion of the contact part 112a. Therefore, the cutout 118a can be easily formed. In addition, in order to engage the engagement part 125a and the cutout 118a, it is sufficient that the worker inserts the engagement part 125a into the cutout 118a from the side surface of the contact part 112a, thus facilitating the operation. Therefore, the workability can be further increased.

In the foregoing description, the busbar 11a and the heat absorption member 12a were taken as an example. However, it goes without saying that the busbar 11b and the heat absorption member 12b are similarly configured to obtain similar advantageous effects.

Components similar to those in the first embodiment are given identical reference signs and detailed descriptions thereof are omitted.

### FOURTH EMBODIMENT

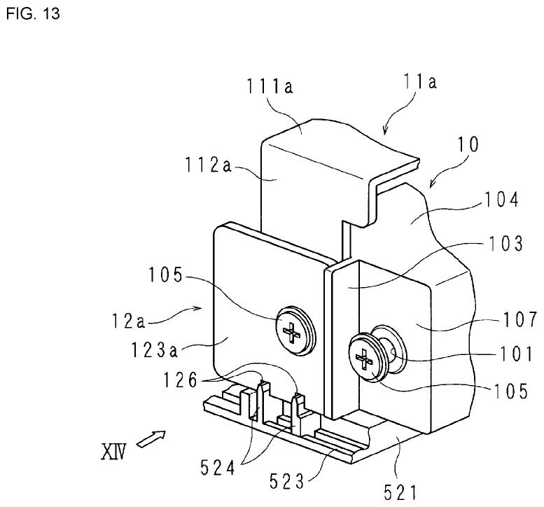

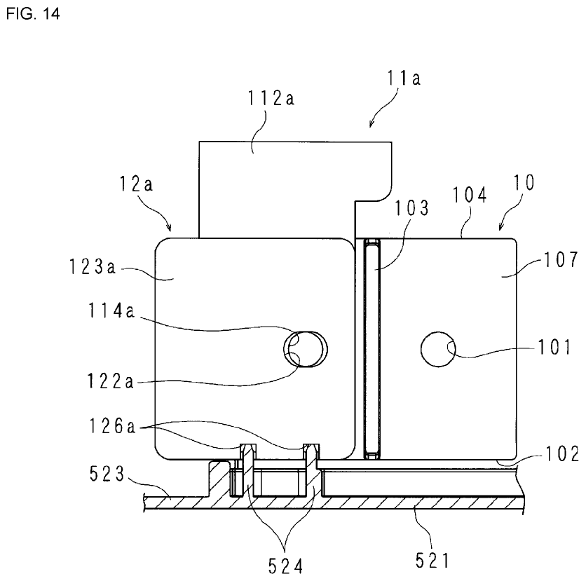

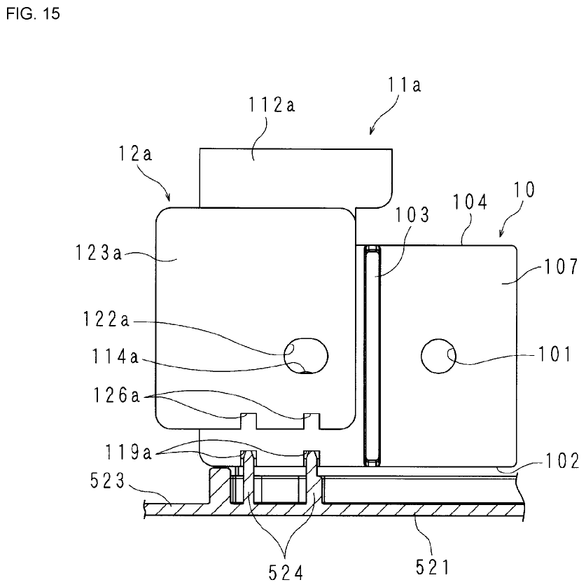

FIG. 13 is a diagram showing a positional relationship between the busbar 11a and the heat absorption member 12a in the electrical junction box 100 according to a fourth embodiment. FIG. 14 is an arrow diagram taken along the arrow XIV in FIG. 13. FIG. 15 is a diagram showing a state in which the position of the heat absorption member 12a in FIG. 14 is shifted. FIGS. 13 to 15 partially show the relay 10, the busbar 11a, the heat absorption member 12a, and the bottom plate 521 for the sake of convenience, and FIGS. 14 and 15 do not show bolts 105 for the sake of convenience.

The electrical junction box 100 according to the fourth embodiment includes busbars 11a and 11b and heat absorption member 12a and 12b similarly to the first embodiment. The busbars 11a and 11b have substantially the same shape, the heat absorption member 12a and 12b have substantially the same shape, and the positional relationship between the busbar 11a and the heat absorption member 12a is similar to the positional relationship between the busbar 11b and the heat absorption member 12b. Therefore, in the following description, the busbar 11a and the heat absorption member 12a will be taken as an example with reference to FIGS. 13 to 15, and a description of the busbar 11b and the heat absorption member 12b will be omitted.

In the fourth embodiment, the busbar 11a is provided closer to the ceiling plate 513 (not shown) than the relay 10. The busbar 11a has a flat plate part 111a, a contact part 112a, and a fixing part 113a (not shown) similarly to the first embodiment. The flat part 111a is interposed between another surface 104 of the relay 10 and the ceiling plate 513, and faces the other surface 104. The contact part 112a and the fixation part 113a are respectively connected to two ends of the flat part 111a and extend toward the bottom plate 521.

The contact part 112a has a substantially rectangular shape whose vertical direction is the longitudinal direction, and is adjacent to the side surface 107 of the relay 10 with one surface thereof facing the side surface 107. The contact part 112a has the through hole 114a (see FIG. 14) at a substantially central portion in the vertical direction. The contact part 112a has two recessed engagement parts 119a (see FIG. 15) that respectively engage with engagement protrusions 524 of the bottom plate 521 described later, at the side edge portion closer to the bottom plate 521. The two recessed engagement parts 119a are rectangular and are separated from each other with a predetermined space therebetween.

As in the first embodiment, the heat absorption member 12a is attached to the other surface of the contact part 112a of the busbar 11a.

The heat absorption member 12a has the rectangular plate 123a. The vertical length of the rectangular plate 123a is shorter than the vertical length of the contact part 112a, and the horizontal length of the rectangular plate 123a is longer than the horizontal length of the contact part 112a. The rectangular plate 123a has the through hole 122a that extends therethrough in the thickness direction at a substantially central portion in the vertical direction (see FIG. 14). The rectangular plate 123a also has two recessed engagement parts 126a that engage with the engagement protrusions 524 of the bottom plate 521, at the side edge portion closer to the bottom plate 521 (see FIGS. 14 and 15). The two recessed engagement parts 126a are rectangular and are separated from each other with a predetermined space therebetween. In the direction in which the heat absorption member 12a and the contact part 112a face each other, the positions of the recessed engagement parts 126a of the heat absorption member 12a correspond to the positions of the recessed engagement parts 119a of the contact part 112a.

In the fourth embodiment, the inside surface 523 of the bottom plate 521 has two engagement protrusions 524 that engage with the recessed engagement parts 126a of the heat absorption member 12a and the recessed engagement parts 119a of the contact part 112a. The engagement protrusions 524 are formed at positions corresponding to the recessed engagement parts 126a of the heat absorption member 12a and the recessed engagement parts 119a of the contact part 112a in the vertical direction, and extend along the direction in which the heat absorption member 12a and the contact part 112a face each other. In addition, each engagement protrusion 524 has a thin strip shape that is substantially elongated in a cross-sectional view, and has a leading end portion that is chamfered. The engagement protrusions 524 are formed as one piece with the bottom plate 521.

When the engagement protrusions 524 engage with the recessed engagement parts 126a of the heat absorption member 12a and the recessed engagement parts 119a of the contact part 112a, the position of the through hole 122a of the rectangular plate 123a is aligned with the position of the through hole 114a of the contact part 112a, as shown in FIG. 14.

As described above, when the through hole 122a of the rectangular plate 123a and the through hole 114a of the contact part 112a are aligned with each other, the bolt 105 is inserted into the through hole 122a and the through hole 114a and screwed to the terminal 101 of the relay 10 so that the heat absorption member 12a and the contact part 112a (the busbar 11a) are fixed to the terminal 101 (see FIG. 13). The busbar 11a is electrically connected to the terminal 101 of the relay 10, and the heat absorption member 12a is pressure-welded to the busbar 11a.

Therefore, in the electrical junction box 100 according to the fourth embodiment, heat generated by the relay 10 during power distribution is quickly absorbed by the heat absorption member 12a via the contact part 112a. This makes it possible to suppress an excessive temperature increase in the relay 10 and the contact part 112a.

When assembling the electrical junction box 100 according to the fourth embodiment, a worker can align the through hole 122a of the rectangular plate 123a and the through hole 114a of the contact part 112a only by engaging the engagement protrusions 524 with the recessed engagement parts 126a of the heat absorption member 12a and the recessed engagement parts 119a of the contact part 112a. This makes it easy to insert the bolt 105 into the through hole 122a of the rectangular plate 123a and the through hole 114a of the contact part 112a and screw the bolt 105 into the terminal 101, thus increasing the workability.

In the foregoing description, the busbar 11a and the heat absorption member 12a were taken as an example. However, it goes without saying that the busbar 11b and the heat absorption member 12b are similarly configured to obtain similar advantageous effects.

Components similar to those in the first embodiment are given identical reference signs and a detailed description thereof is omitted.

The embodiments described above are illustrative and are not limitative in all respects. It should be noted that the scope of the present disclosure is not indicated by the embodiments described above, but is indicated by the claims, and is intended to include all modifications within a meaning and scope equivalent to the claims.

1. An electrical junction box for a vehicle, the electrical junction box including a busbar that has a through hole at one end portion and is screwed to an electronic component using the through hole, the electrical junction box comprising
a heat absorption member that is attached to the one end portion and absorbs heat from the electronic component,
wherein the heat absorption member has a corresponding through hole that corresponds to the through hole and an engagement part that engages with the busbar.

2. The electrical junction box according to claim 1, wherein the busbar has an engagement through hole that engages with the engagement part.

3. The electrical junction box according to claim 1, wherein the engagement part has a hook shape.

4. The electrical junction box according to claim 1, wherein the busbar is provided with a cutout that engages with the engagement part, at a side edge of the busbar.

5. The electrical junction box according to claim 1, wherein the heat absorption member is made of copper or aluminum.

6. The electrical junction box according to claim 2, wherein the engagement part has a hook shape.

7. The electrical junction box according to 2, wherein the heat absorption member is made of copper or aluminum.

8. The electrical junction box according to 3, wherein the heat absorption member is made of copper or aluminum.

9. The electrical junction box according to 4, wherein the heat absorption member is made of copper or aluminum.
